(19) United States
(12) Patent Application Publication
(10) Pub. No.: US 2016/0069948 A1
(43) Pub. Date: Mar. 10, 2016

(54) ANALYZING APPARATUS

(71) Applicant: KABUSHIKI KAISHA TOSHIBA, Tokyo (JP)

(72) Inventor: Satoshi IKARASHI, Yokohama Kanagawa (JP)

(21) Appl. No.: 14/630,501

(22) Filed: Feb. 24, 2015

(30) Foreign Application Priority Data
Sep. 10, 2014 (JP) 2014-184357

(51) Int. Cl. G01R 31/28

(52) U.S. Cl. CPC G01R 31/2813

(57) ABSTRACT

An analyzing apparatus for a semiconductor device includes an image acquiring unit configured to acquire an image of a sample and generate image data of the acquired image, a specifying unit configured to specify a failure position of the sample based on the image data, and a marking unit configured to make a mark on a surface position of the sample that corresponds to the failure position as specified by the specifying unit.

### CROSS-REFERENCE TO RELATED APPLICATION

This application is based upon and claims the benefit of priority from Japanese Patent Application No. 2014-184357, filed Sep. 10, 2014, the entire contents of which are incorporated herein by reference.

### FIELD

Embodiments described herein relate generally to an analyzing apparatus.

### BACKGROUND

An electronic device such as a semiconductor element and a liquid crystal display apparatus is becoming miniaturized and advanced According to the miniaturization of the electronic device, analyzing technology to specify defects and failures of the electronic device becomes complicated.

### DESCRIPTION OF THE DRAWINGS

FIG. 1 is a block diagram illustrating an analyzing apparatus according to a first embodiment.

FIGS. 2A to 2E are block diagrams schematically illustrating examples of a marking unit of the analyzing apparatus.

FIG. 3 is a flowchart of steps performed during a failure analysis of a semiconductor element.

FIG. 4 is a flowchart of steps included in a nondestructive step performed in the failure analysis of the semiconductor element.

FIG. 5A is an image of an internal structure of a measuring target sample obtained using an X-ray analyzing apparatus, and FIG. 5B is an example of a design image of pins and wiring of the measuring target sample.

FIGS. 6A to 6C schematically illustrate an internal structure image of the measuring target sample obtained using a Scanning Acoustic Tomograph. FIG. 6A illustrates an image obtained by using transmitted waves of ultrasonic waves, FIG. 6B illustrates an image obtained by using reflected waves of the ultrasonic waves, and FIG. 6C illustrates an image obtained by changing a focus position from the one used to obtain the image in FIG. 6B.

FIG. 7 is a block diagram of an analyzing apparatus according to a second embodiment.

FIG. 8 is a block diagram of an analyzing apparatus according to a third embodiment.

FIG. 9 is a block diagram of an analyzing apparatus according to a fourth embodiment.

### DETAILED DESCRIPTION

The present embodiment now will be described more fully hereinafter with reference to the accompanying drawings, in which various embodiments are shown. In the drawings, the thickness of layers and regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to limit the scope of the invention. As used herein, the singular forms “a,” “an” and “the” are intended to include the plurality of forms as well, unless the context clearly indicates otherwise. It will be further understood that the terms “comprises,” “comprising,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (and/or variations thereof), it may be directly on or extend directly onto the other element or intervening elements may also be present. In contrast, when an element is referred to as being “directly on” or extending “directly onto” another element (and/or variations thereof), there are no intervening elements present. It will also be understood that when an element is referred to as being “connected” or “coupled” to another element (and/or variations thereof), it may be directly connected or coupled to the other element or intervening elements may be present. In contrast, when an element is referred to as being “directly connected” or “directly coupled” to another element (and/or variations thereof), there are no intervening elements present.

It will be understood that, although the terms first, second, etc. may be used herein to describe various elements, components, regions, layers and/or sections, these elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, if the structure in the Figure is turned over, elements described as being on the “backside” of substrate would then be oriented on “upper” surface of the substrate. The exemplary term “upper”, may therefore, encompasses both an orientation of “lower” and “upper,” depending on the particular orientation of the figure. Similarly, if the structure in one of the figures is turned over, elements described as “below” or “beneath” other elements would then be oriented “above” the other elements. The exemplary terms “below” or “beneath” can, therefore, encompass both an orientation of above and below.

Embodiments are described herein with reference to cross section and perspective illustrations that are schematic illustrations of idealized embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

Embodiments provide an analyzing apparatus capable of efficiently performing failure analysis of a semiconductor element, a liquid crystal display apparatus, and the like.

In general, according to one embodiment, an analyzing apparatus for a semiconductor device includes an image acquiring unit configured to acquire an image of a sample and generate image data of the acquired image, a specifying unit configured to specify a failure position of the sample based on the image data, and a marking unit configured to make a mark on a surface position of the sample that corresponds to the failure position as specified by the specifying unit.

Hereinafter, embodiments will be described with reference to the drawings.

The drawings are schematic or conceptual, and a relationship between a thickness and a width of each portion, a ratio of a size between portions, and the like may not be same as real things. Furthermore, even for the same portion, mutual dimensions and ratios may be different depending on the drawings. Furthermore, in this specification and each drawing, the same reference numerals are given to the same elements and detailed description will be appropriately omitted.

### First Embodiment

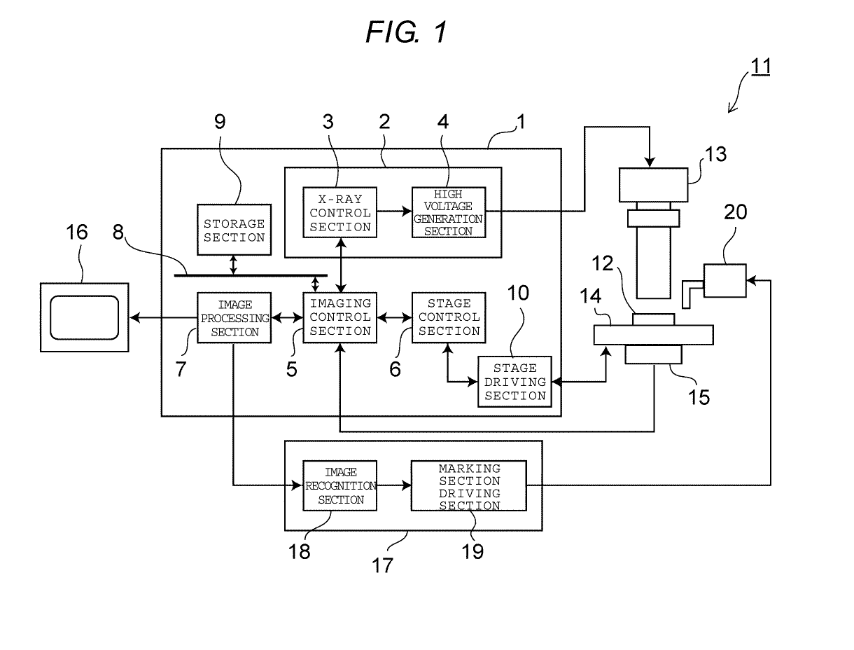

FIG. 1 is a block diagram illustrating a configuration of an analyzing apparatus 11 according to the embodiment.

The analyzing apparatus 11 according to the embodiment includes a body 1, an X-ray irradiation unit 13, a stage 14, an X-ray camera 15, a failure position specifying unit 17, and a marking unit 20. The analyzing apparatus 11 is a so-called X-ray analyzing apparatus (X-ray microscope). The analyzing apparatus 11 acquires image data of an internal structure of a measuring target sample 12 by applying X-ray to the measuring target sample 12 and detecting transmitted X-ray with the X-ray camera 15. Moreover, hereinafter, the X-ray analyzing apparatus will be described and the embodiment may be applied to an optical microscope by changing the X-ray to a visible light and may be applied to another analyzing apparatus using an arbitrary wavelength.

The body 1 is connected to the X-ray irradiation unit 13, the stage 14, the X-ray camera 15, and the failure position specifying unit 17. The failure position specifying unit 17 is connected to the marking unit 20. The body 1 appropriately operates each unit by transmitting a signal to each unit.

The body 1 includes an X-ray generation unit 2, an imaging control unit 5, a stage control unit 6, an image processing unit 7, an internal bus 8, and a storage unit 9.

The X-ray generation unit 2 is respectively connected to the X-ray irradiation unit 13 and the imaging control unit 5. The X-ray generation unit 2 includes an X-ray control unit 3 and a high voltage generation unit 4. The X-ray control unit of the X-ray generation unit 2 receives irradiation instruction of the X-ray, for example, from an external controller (not illustrated) and actuates the high voltage generation unit 4 based on a received signal. The high voltage generation unit 4 generates a high voltage and drives the X-ray irradiation unit 13. The irradiation instruction of the X-ray may include, for example, a magnification, a scanning range, a resolution, and the like when imaging the measuring target sample 12.

The imaging control unit 5 is connected to the X-ray control unit 3 and receives a signal informing a situation such as an operation state of the X-ray irradiation unit 13 from the X-ray irradiation unit 13. For example, the operation state of the X-ray irradiation unit 13 is a signal indicating that the X-ray control unit 3 starts driving of the X-ray irradiation unit 13 using the high voltage generation unit 4 or is a signal indicating that the driving of the X-ray irradiation unit 13 is completed. The imaging control unit receives the signals, starts or completes an imaging operation by the X-ray camera 15.

The imaging control unit 5 is connected to the stage control unit 6 and transmits positional information of the stage 14 to the stage control unit 6. The positional information of the stage 14 is input from the external controller and the like into the imaging control unit 5.

The imaging control unit 5 is connected to the X-ray camera 15 and captures an image based on the X-ray image transmitted through the measuring target sample 12. The imaging control unit 5 is connected to the image processing unit 7 and transmits an image signal generated from the X-ray camera 15 to the image processing unit 7. The imaging control unit 5 stores image data processed by the image processing unit 7 in the storage unit 9 through the internal bus 8. The imaging control unit 5 can read processing data including the image data stored in the storage unit 9 and transmit the processing data to the image processing unit 7.

For example, the imaging control unit 5 includes a Central Processing Unit (CPU) or a Micro Processing Unit (MPU) and controls the X-ray generation unit 2, the stage control unit 6, and the image processing unit 7 based on an instruction of the external controller and the like. Furthermore, the imaging control unit 5 reads a program from the storage unit 9 through the internal bus 8 and performs each step of the program.

The storage unit 9 may be a semiconductor memory such as a Read Only Memory (ROM) and Random Access Memory (RAM) or may be a storage device such as a magnetic storage medium, an optical magnetic storage medium, and an optical storage medium. The storage unit 9 may be formed of a plurality of recording media.

The stage control unit 6 acquires the positional information from the imaging control unit 5 and drives a stage driving unit 10 based on the positional information. The stage driving unit 10 sets a relative position of the measuring target sample 12 with respect to the X-ray irradiation unit 13 on the stage 14 on which the measuring target sample 12 is mounted. Moreover, since the stage driving unit 10 includes a position sensor, the stage control unit 6 can acquire the position of the stage 14 by receiving positional information of the position sensor of the stage driving unit 10.

The stage driving unit 10 includes a motor, an actuator, or the like that moves the stage 14 and includes a driver circuit or the like that drives the motor or the actuator. Furthermore, the stage driving unit 10 includes a position sensor that detects a relative position between the stage 14 and the X-ray irradiation unit 13. The stage driving unit 10 moves the stage 14 on which the measuring target sample 12 is mounted according to the positional information set by the imaging control unit 5. The stage driving unit 10 moves the stage 14 to an appropriate position with respect to the X-ray irradiation unit 13.

The image processing unit 7 is connected to the failure position specifying unit 17. The image processing unit 7 performs signal processing of the image data captured by the imaging control unit 5 in the body 1. The image processing unit 7 may read the image data stored in the storage unit 9 by the imaging control unit 5 and may read design data including coordinates of the internal structure of the measuring target sample 12 stored in the storage unit 9. For example, the image processing unit 7 may be connected to a monitor 16 and may output processed image data to the monitor 16 as an image.

The X-ray irradiation unit 13 receives a command from the body 1 through a connection with the body 1 and applies the X-ray to the measuring target sample 12 accordingly.

The stage 14 includes a surface on which the measuring target sample 12, which is an object of failure analysis, is mounted in a predetermined region. The relative position of the stage 14 with respect to the X-ray irradiation unit 13 is set to a position corresponding to the positional information received by the stage control unit 6 from the imaging control unit 5.

The X-ray camera 15 captures an X-ray image based on an X-ray that is applied by the X-ray irradiation unit 13 and passing through the measuring target sample 12 and transmits image data of the X-ray image to the imaging control unit 5.

The failure position specifying unit 17 includes an image recognition unit 18 and a marking unit driving unit 19. The image recognition unit 18 is connected to the image processing unit 7 and receives the image data from the image processing unit 7. The marking unit driving unit 19 is connected to the image recognition unit 18 and acquires positional information of the marking unit 20 from the image recognition unit 18. The marking unit 20 is connected to the marking unit driving unit 19, and the marking unit driving unit 19 moves the marking unit 20 based on the acquired positional information. The failure position specifying unit 17 specifies a failure position in the measuring target sample 12 based on the image data generated based on the transmitted X-ray. The failure position specifying unit 17 moves the marking unit 20 to the failure position based on the image signal transmitted from the image processing unit 7 and makes the marking unit 20 perform an marking operation.

The image recognition unit 18 acquires the image data from the image processing unit 7. For example, the image recognition unit 18 reads the image data from the storage unit 9 through the internal bus 8, the imaging control unit 5, and the image processing unit 7. The image recognition unit 18 determines the failure position based on the read image data. The image recognition unit 18 generates the coordinates of the failure position determined to include a failure and transmits the coordinates to the marking unit driving unit 19.

When the failure position is determined by the image recognition unit 18, the image recognition unit 18 may use the design data including the coordinates of the internal structure such as Computer Aided Design (CAD) data regarding the measuring target sample 12.

More specifically, the image recognition unit 18 stores in advance the design data (CAD data) including the coordinate data of the measuring target sample 12 in the storage unit 9 and compares the X-ray image data of the measuring target sample 12 with the design data. The image recognition unit 18 extracts a characteristic portion having characteristic parameters of the input image data and associates the characteristic portion with the design data. For example, the characteristic portion may include shape data, size data of a bonding pad, and the like. Each characteristic portion associated with the design data has coordinate data based on the design data. The characteristic portion of the image data that is not associated with the design data does not have the coordinate data. Thus, the image recognition unit 18 calculates the coordinate data by performing a supplement process using the coordinate data of the characteristic portion at a periphery of the characteristic portion that is not associated with the design data. For example, since the failure position due to attachment of a foreign matter on a chip surface does not exist in the design data, the image recognition unit 18 may extract the characteristic portion of the detected foreign matter as the characteristic portion that is not associated with the design data through the procedure as described above, and may specify the characteristic portion as the failure position by assigning the coordinate data. The failure position specifying unit 17 may specify the failure position by extracting the failure position using a known image recognition technology. Moreover, in the analyzing apparatus of the embodiment, the image recognition unit 18 may cause the monitor 16 to display the design data including the read coordinate data and the image data of the X-ray image so as to superimpose each other. Thus, an analyst may acquire the coordinates of the failure position through visual observation of the monitor 16.

The marking unit driving unit 19 receives the coordinate data of the failure position acquired by the image recognition unit 18 and moves the marking unit 20 to the position corresponding to the coordinate data. The marking unit driving unit 19 drives the marking unit 20 so as to apply a mark on the measuring target sample 12 by the marking unit 20 located at position coordinates of the failure position.

The marking unit 20 acquires the coordinate data of the specified failure position and is moved to an appropriate position by the marking unit driving unit 19. The marking unit 20 receives a drive signal for applying a mark indicating the failure position on the measuring target sample 12 through the marking unit driving unit 19 and applies the mark on a position corresponding to the failure position on the measuring target sample 12. Since defects of the semiconductor element are generated inside the measuring target sample 12, marking may not be directly performed on the failure position of the measuring target sample 12. In such a situation, for example, a position of a package surface corresponding to the position of the measuring target sample 12 in which the failure is actually generated is set as a failure position. The marking unit 20 may move to a relative position corresponding to the failure position in which the failure is generated on the measuring target sample 12. For example, the marking unit 20 may be fixed to a column (not illustrated) other than the X-ray irradiation unit 13 and the stage 14, and may be relatively moved with respect to the stage 14. Alternatively, the marking unit 20 may be fixed to the X-ray irradiation unit 13. When the marking unit 20 is fixed to the X-ray irradiation unit 13, the relative position with respect to the stage 14 can be set. In this case, the relative position of marking unit 20 with respect to the stage 14 may be set by the stage control unit 6 and the stage driving unit 10. Furthermore, the marking unit 20 may be fixed to the stage 14, may be driven through the marking unit driving unit 19, and may be relatively moved with respect to the stage 14.

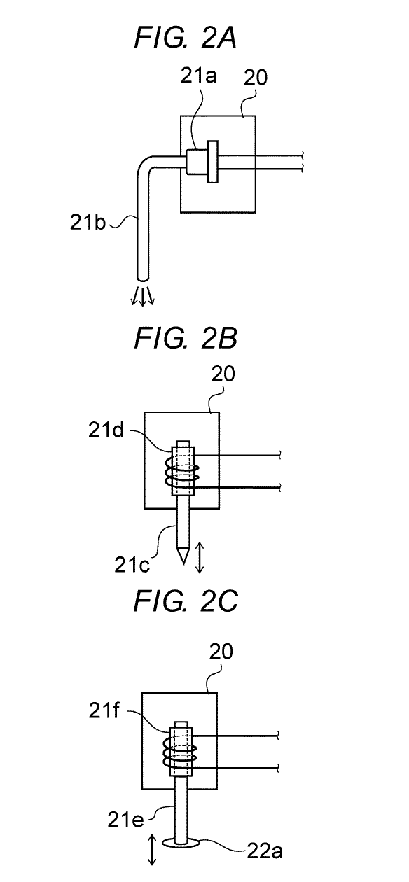

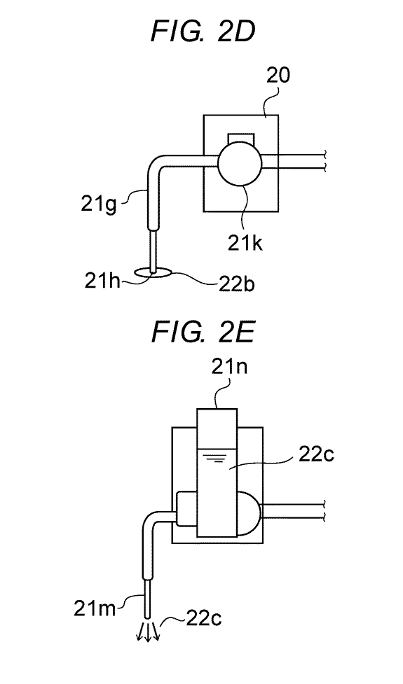

FIGS. 2A to 2E are block diagrams schematically illustrating a configuration example of the marking unit 20.

As illustrated in FIG. 2A, for example, the marking unit 20 includes a laser emitter 21a. The marking unit 20 includes a light guiding body 21b guiding the laser beam so as to apply the laser beam output from the laser emitter 21a to an appropriate position of the surface of the measuring target sample 12. The light guiding body 21b is, for example, an optical fiber. If the marking unit 20 includes the laser emitter 21a, the marking unit driving unit 19 includes a laser oscillator that drives the laser emitter 21a. The marking unit 20 applies the laser beam to the position corresponding to the failure position on the surface of the measuring target sample 12 according to a marking signal from the marking unit driving unit 19. The laser beam may be applied on the measuring target sample 12 by being divided in several times in a pulse shape. If the measuring target sample 12 is a semiconductor element sealed by a resin or a BGA, and the like, the position to which the laser beam is applied indicates the position corresponding to the failure position in which the surface of the measuring target sample 12 is laser processed.

As illustrated in FIG. 2B, for example, the marking unit 20 includes a scriber 21c of which a tip is sharp and a solenoid driving circuit 21d which moves the scriber 21c so as to abut the position corresponding to the failure position on the surface of the measuring target sample 12. The marking unit 20 moves the tip of the scriber 21c so as to abut the surface of the measuring target sample 12 by supplying a driving current to the solenoid driving circuit 21d. The scriber 21c marks the position corresponding to the failure position by scratching the surface of the measuring target sample 12 with the abutting tip.

As illustrated in FIG. 2C, the marking unit 20 may include a rod-shaped member 21e, and a label 22a on which adhesive is coated on both sides may be attached to the tip of the rod-shaped member 21e. In the marking unit 20, the tip of the rod-shaped member 21e is pressed against the surface the measuring target sample 12 by a solenoid driving circuit 21f. The rod-shaped member 21e presses and attaches the label 22a to the position corresponding to the failure position of the surface of the measuring target sample 12.

As illustrated in FIG. 2D, the marking unit 20 includes a suction chuck 21g including a suction port 21h at the tip and a suction pump 21k sucking air from the suction port 21h. The marking unit 20 sucks a label 22b on which adhesive is coated on one surface on a side of the measuring target sample 12 at the suction port 21h. The suction chuck 21g presses and attaches the label 22b against the position corresponding to the failure position on the surface of the measuring target sample 12.

The labels 22a and 22b attached to the measuring target sample 12 are preferably formed of a metal material through which the X-ray and the like are not transmitted after being attached or on the labels 22a and 22b. Alternatively, ink and the like containing a metal material is preferably coated. Since metal is contained in the labels 22a and 22b, the X-ray and the like cannot be transmitted through the labels 22a and 22b. Thus, the analyst may use the labels 22a and 22b attached to the measuring target sample 12 as a mark when performing the X-ray analysis or another analysis in a subsequent process.

As illustrated in FIG. 2E, for example, the marking unit 20 may be a nozzle 21m ejecting an ejection material 22c such as powder or liquid. The marking unit 20 includes a tank 21n storing the ejection material 22c ejected from the nozzle 21m. The marking unit 20 ejects the ejection material 22c from a tip of the nozzle 21m by compressing air or the ejection material in the tank 21n. The nozzle 21m of the marking unit 20 ejects the ink or powder and attaches the ink or the powder to the position corresponding to the failure position on the measuring target sample 12. Since the X-ray and the like cannot be transmitted through the ink or powder containing the metal material, the analyst using the analyzing apparatus 11 may use the ink or powder attached to the measuring target sample 12 as a mark when performing the X-ray analysis or another analysis in a subsequent process.

Photocurable or thermosetting conductive paste may be ejected from the nozzle 21m of the marking unit 20. If the failure position cannot be identified, the marking unit 20 may attach the conductive paste on a plurality of candidate positions on the measuring target sample 12 using the nozzle 21m. Further, after another analysis is performed, ultraviolet ray or hot air may be applied to and cure the conductive paste on remaining candidate positions. Since the conductive paste contains the metal material, the mark formed with the conductive paste does not transmit the X-ray and the like.

In any case, if in the BGA package semiconductor element a length of one side of an exterior shape of the measuring target sample 12 is approximately 11 mm to 12 mm, a diameter of the mark for marking is preferably approximately 0.5 mm. Moreover, a size and a shape of the mark for marking may be set arbitrarily.

The marking unit 20 may include at least one of the configurations illustrated in FIGS. 2A to 2E. The marking unit 20 may include a plurality of the configurations. When the marking unit 20 includes the plurality of configurations, each configuration may be detachable. For example, the configurations may be changed depending on a material of the surface of the measuring target sample or an order of analysis.

The analyzing apparatus 11 according to the embodiment is operated as below.

In the analyzing apparatus 11, the X-ray irradiation unit 13 applies X-ray to the measuring target sample 12, and the X-ray camera 15 acquires the X-ray image.

Further, in the analyzing apparatus 11, the imaging control unit 5 of the body 1 captures the acquired X-ray image, and the image processing unit 7 generates image data that is image-processed.

In the analyzing apparatus 11, the image recognition unit 18 of the failure position specifying unit 17 detects and specifies the failure position based on the generated image data, and the marking unit 20 is moved to the position corresponding to the failure position on the measuring target sample 12.

The marking unit 20 is driven by the marking unit driving unit 19 and marks the position corresponding to the failure position on the measuring target sample 12.

As described above, the analyzing apparatus 11 may specify the failure position through image processing of the image data acquired by the X-ray camera 15, move the marking unit 20 to the position corresponding to the failure position on the measuring target sample 12, and then apply a predetermined mark to the position corresponding to the failure position on the measuring target sample 12. Since the analyst using the analyzing apparatus 11 does not need to manually compare the image data with design data of the measuring target sample 12 and the like, it is possible to efficiently conduct the failure analysis of the measuring target sample 12. Furthermore, since the analyzing apparatus 11 may accurately specify the position corresponding to the failure position on the measuring target sample 12 with the failure position specifying unit 17 and the marking unit 20, the analyst may further efficiently perform the failure analysis.

The semiconductor element, the liquid crystal display apparatus, or the like advances every year. In such a field, precision of a device advances and an element having a complicated structure such as a three-dimensional structure is generally adapted in micro processing technology. Identifying the failure cause of such a micro structure element and performing accurate feedback to a manufacturing process and the like are an important matter to achieve a higher performance of the device. Causes of a failure in such a high-performance device are diverse and complex. Recently, when performing these failure analyses, it is possible to use the analyzing apparatus having a high function and a high performance. In order to obtain an appropriate result using such an analyzing apparatus, it is important for the analyst to use an appropriate analyzing apparatus according to the cause of the failure. Thus, for the analyst, it is necessary to make a proper evaluation plan and perform the failure analysis.

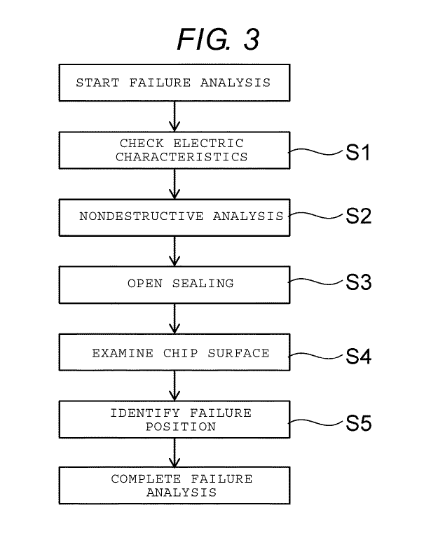

FIG. 3 is a flowchart illustrating an example of a procedure of a general failure analysis of the semiconductor element.

In step S1, an analyst checks electric characteristics of the measuring target sample. To check the electric characteristics of the measuring target sample, for example, the analyst may use a semiconductor tester, a curve tracer, and the like. The analyst may predict in which path and between which terminals the failure exists by checking the electric characteristics.

In step S2, the analyst selects an optimal analyzing apparatus based on a possible cause of the failure, and analyzes the failure using the selected apparatus. The analyst compares the analysis result and the failure of the electric characteristics, and specifies the failure position.

In step S3, the analyst performs opening of the sealing resin or the like of the measuring target sample according to the analysis result of step S2. When opening the resin, the analyst removes a part of the vicinity of the failure position or the entire sealing resin, as necessary.

In step S4, the analyst performs exterior inspection of the chip surface using an optical microscope or an electron microscope, or checks the electric characteristics using a prober and the like.

In step S5, the analyst specifies the failure position and the cause of the failure, and checks whether or not there is a of correlation between the failure position and the cause specified in step 2 and the failure position and the cause of the failure specified in the initial step (step S2).

For example, in step S2, when the failure such as burning, abnormalities of a structure such as wire deformation, and the like inside the measuring target sample are recognized, the analyst needs to specify the failure position and the cause of the failure in further detail. However, when the failure sample is opened to inspect the failure position on the inside of the measuring target sample, since the sample cannot be returned to a previous state, it is necessary for the analyst to carefully determine whether to open the measuring target sample. Thus, it is necessary for the analyst to appropriately use a nondestructive analyzing apparatus and obtain an appropriate result.

Meanwhile, the analyzing apparatus is excellent in failure detection sensitivity with respect to a specific cause of a failure, but may not detect other causes of failures. For example, like the X-ray analyzing apparatus or the Scanning Acoustic Tomograph, some analyzing apparatuses may specify the failure position after performing adjustment such as focusing with respect to the specific failure position. Thus, it is necessary for the analyst to use a plurality of apparatuses or use a single apparatus in several times.

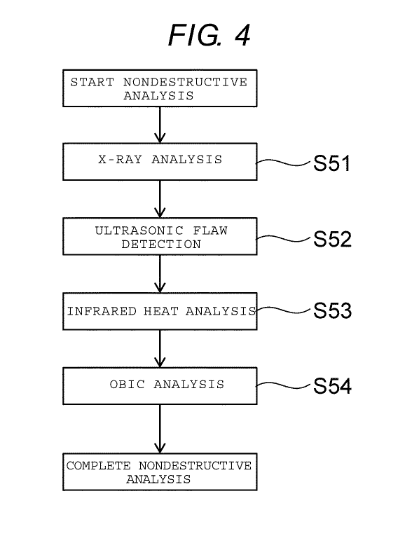

FIG. 4 is a flowchart illustrating an example of a procedure of the nondestructive analysis in step S2 of FIG. 3.

In step S51, the analyst acquires the internal structure of the measuring target sample using the X-ray analyzing apparatus. If there is a structural problem such as wire open, it is possible to detect the failure by the X-ray analyzing apparatus.

In step S52, the analyst may use a Scanning Acoustic Tomograph (SAT) to detect a three dimensional structural defect of a peeling state or the like of the sealing resin of the chip surf ace.

In step S53, the analyst may use an infrared heat analyzing apparatus to detect a leak position or the like of the measuring target sample in three dimensions.

In step S54, the analyst may an OBIC/OBIRCH analyzing apparatus to detect a micro leak position. When the OBIC/OBIRCH analyzing apparatus is used, infrared laser beam may be applied from a rear surface after the rear surface of the semiconductor element is polished. If so, the SAT analysis or the like cannot be performed after the analysis is performed.

As described above, in many cases, the analyst uses the apparatus by combining at least two or more types of analyzing apparatuses out of the X-ray analyzing apparatus, the Scanning Acoustic Tomograph, the infrared heat analyzing apparatus, the OBIC/OBIRCH analyzing apparatus, and the like. Furthermore, the analyst may use various analyzing apparatuses for inspecting the surface of the chip and the like after the measuring target sample is opened.

In any analyzing apparatus, if a position having a failure is found, the analyst intensively inspects the position in the analysis thereafter. If the failure position is found, it is necessary to reset the measuring target sample to another analyzing apparatus, but it is unclear that which position is the failure position unless applying some mark.

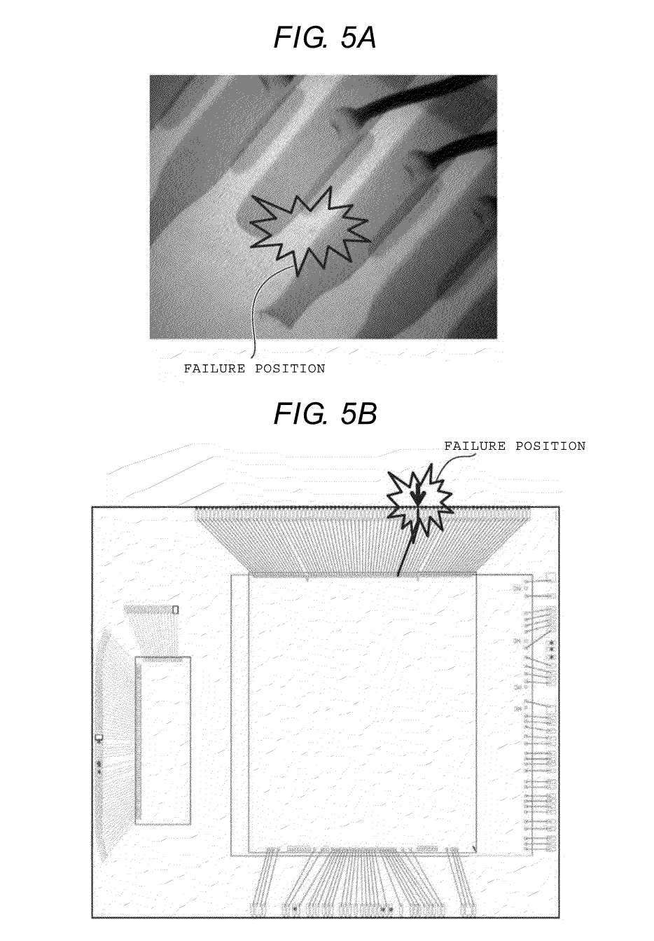

FIG. 5A is an image example of a part of an internal state of the semiconductor element captured using the X-ray analyzing apparatus. FIG. 5B is an example of the design data indicating a physical pin disposition in the semiconductor element of the image example of FIG. 5A.

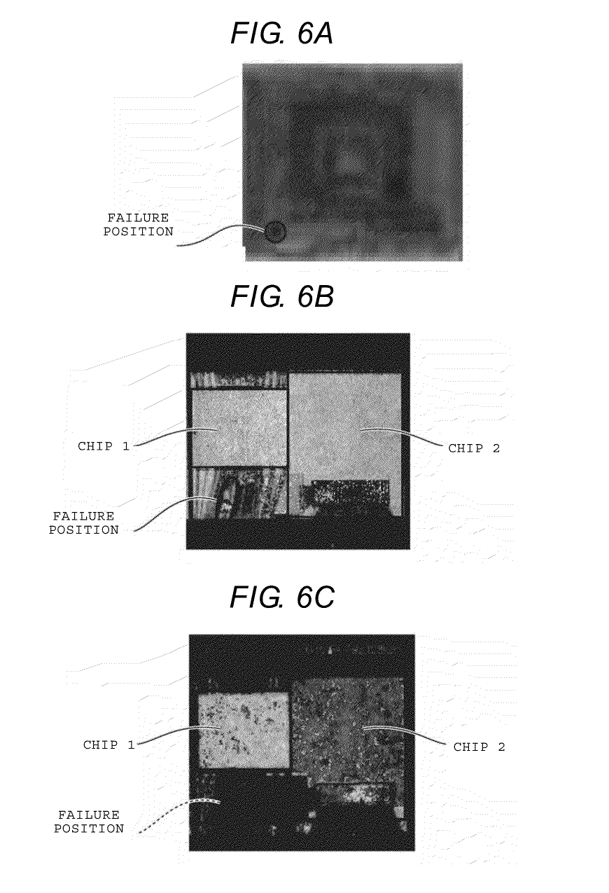

FIGS. 6A to 6C schematically illustrate image examples of a part of an internal state of the same semiconductor element captured using the Scanning Acoustic Tomograph. FIG. 6A is an image example captured using transmission ultrasonic waves. FIGS. 6B and 6C are image examples captured using reflected waves of the ultrasonic waves and are imaging examples in which focus positions are different from each other. Moreover, for the measuring target sample, a multi-chip module (Multi-Chip Package) product in which a chip 1 and a chip 2 are sealed is used.

For example, as illustrated in FIG. 5A, if a shadow of a foreign matter is observed between lead terminals through an analysis using the X-ray analyzing apparatus, it is necessary for the analyst to particularly specify the position of the foreign matter. Thus, for example, the analyst specifies what numbers terminals between which a foreign matter exists are from the right side by referring to the design data as FIG. 5B while changing a scanning range or magnification of the X-ray analyzing apparatus.

As illustrated in FIG. 6A, the Scanning Acoustic Tomograph, can detect the failure position using transmitted ultrasonic waves. The Scanning Acoustic Tomograph, in order to further clearly specify the failure position, may use reflected ultrasonic waves. As illustrated in FIGS. 6B and 6C, the analyst can acquire different reflected wave images by changing the focus position, and specify the failure position. In FIG. 6B, the focus of the image is on the chip 1, and in FIG. 6C the focus of the image is on the chip 2. As described above, in the failure analysis using the Scanning Acoustic Tomograph, since the failure position needs to be searched for not only in the coordinate position on a two-dimensional plane but also in a three dimensional direction, it takes a long time to perform the analysis work.

If each analysis work described above is processed without applying the mark, the analyst has to find the failure position in each analysis step and efficiency of the analysis is reduced. Furthermore, if the measuring target sample is opened, it is difficult to manually apply the mark on the surface of the chip.

In the analyzing apparatus 11 according to the embodiment, if the failure is found, it is possible to specify the failure position by the failure position specifying unit 17. In the analyzing apparatus 11, the marking unit 20 may be automatically moved to the failure position by the failure position specifying unit 17 and apply the mark on the failure position. Thus, the analyst may remarkably improve the efficiency of the analysis. Furthermore, in the analyzing apparatus 11 of the embodiment, since the failure position may be specified with the exact coordinates by the failure position specifying unit 17, the analyst may remarkably improve the accuracy of the analysis work compared to a case where the mark is applied on the measuring target sample 12 manually.

### Second Embodiment

In the first embodiment, the analyzing apparatus is described based on the X-ray analyzing apparatus, but the analyzing apparatus may be also applied to a Scanning Acoustic Tomograph. The Scanning Acoustic Tomograph emits ultrasonic waves to a measuring target sample placed in water, acquires the reflected waves or transmitted waves and the transmission ultrasonic waves, and performs signal processing. As a result, the image data of the inside of the measuring target sample is acquired.

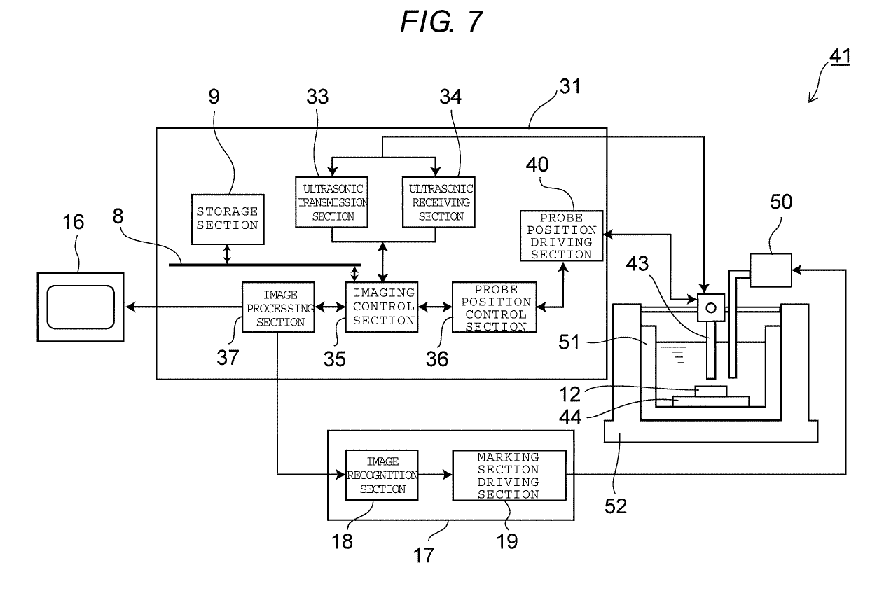

FIG. 7 is a block diagram illustrating a configuration of an analyzing apparatus 41 according to a second embodiment. The analyzing apparatus 41 according to the embodiment is a Scanning Acoustic Tomograph.

The analyzing apparatus 41 includes a body 31, an ultrasonic probe 43, a stage 44, the failure position specifying unit 17, and a marking unit 50. The analyzing apparatus 41 applies ultrasonic waves to a measuring target sample 12 from the ultrasonic probe 43, receives the reflected ultrasonic waves at the ultrasonic probe 43, and generates in the body 31 an ultrasonic wave image of the measuring target sample 12.

The body 31 is connected to the ultrasonic probe 43, the stage 44, and the failure position specifying unit 17. Furthermore, the failure position specifying unit 17 is connected to the marking unit 50. The body 31 transmits a signal to each unit and appropriately operates each unit.

The body 31 includes an ultrasonic transmission unit 33, an ultrasonic receiving unit 34, an image control unit 35, an ultrasonic probe position control unit 36, an image processing unit 37, the internal bus 8, and the storage unit 9.

The ultrasonic transmission unit 33 is connected to the ultrasonic prove 43 and drives the ultrasonic probe 43. The ultrasonic probe 43 converts an electrical signal transmitted and output by the ultrasonic transmission unit 33 into an ultrasonic signal and outputs the ultrasonic signal.

The ultrasonic receiving unit 34 is connected to the ultrasonic probe 43 and receives the electrical signal of the reflected ultrasonic waves of the measuring target sample 12 that is received by the ultrasonic probe 43 and converted into the electrical signal. The ultrasonic receiving unit 34 transfers the signal of the received reflected waves to the image control unit 35.

The image control unit 35 acquires the ultrasonic signal for generating the ultrasonic image from the ultrasonic transmission unit 33 and the ultrasonic receiving unit 34.

The image control unit 35 is connected to the ultrasonic probe position control unit 36 and transmits positional information regarding a relative position of the ultrasonic probe 43 with respect to the stage 44 to the ultrasonic probe position control unit 36.

The image control unit 35 is connected to the image processing unit 37 and transfers the electrical signal converted from the ultrasonic waves acquired by the ultrasonic transmission unit 33 and the ultrasonic receiving unit 34. The image control unit 35 accumulates the image data that is processed by the image processing unit 37 in the storage unit 9 through the internal bus 8. The image control unit 35 may read the processing data including the image data accumulated in the storage unit 9 and may transmit the processing data to the image processing unit 37.

For example, the image control unit 35 is a Central Processing Unit (CPU), a Micro Processing Unit (MPU), or the like, and controls the ultrasonic probe position control unit 36 and the image processing unit 37 based on an instruction from an external controller and the like. Furthermore, the image control unit 35 reads a program from the storage unit 9 and performs each step of the program.

Since the internal bus 8 and the storage unit 9 are the same as those in the analyzing apparatus according to the first embodiment, the description will be omitted.

The ultrasonic probe position control unit 36 acquires positional information from the image control unit 35 and drives an ultrasonic probe position driving unit 40 based on the positional information. The ultrasonic probe position control unit 36 sets the relative position of the ultrasonic probe 43 with respect to the measuring target sample 12. If the stage 44 is a turn table, the ultrasonic probe position control unit 36 may set angle information of the stage 44. Furthermore, if the ultrasonic probe 43 is rotated about a transmitting direction of the ultrasonic waves as an axis, the ultrasonic probe position control unit 36 may set the angle information of the ultrasonic probe 43. A relative position of the ultrasonic probe 43 with respect to the stage 44 is detected by a position sensor included in the ultrasonic probe position driving unit 40, and the ultrasonic probe position control unit 36 receives the positional information through the connection with the ultrasonic probe position driving unit 40.

The ultrasonic probe position driving unit 40 includes a motor or an actuator and the like moving the ultrasonic probe 43 and includes a driver circuit driving the motor or the actuator and the like. The ultrasonic probe position driving unit 40 includes a position sensor that detects the relative position between the ultrasonic probe 43 and the stage 44. The ultrasonic probe 43 moves to the relative position between the measuring target sample 12 and the ultrasonic probe 43 by the ultrasonic probe position driving unit 40.

In the analyzing apparatus 41 according to the embodiment, in order to perform ultrasonic flaw detection of the measuring target sample 12, the measuring target sample 12 is placed in the water. Thus, since the stage 44 on which the measuring target sample 12 is mounted is also placed in the water, the stage 44 is fixed to a water tank 51 and the ultrasonic probe 43 is relatively moved with respect to the stage 44. The ultrasonic probe position driving unit 40 moves the ultrasonic probe 43 to a position that is set in the stage 44 on which the measuring target sample 12 is mounted through connection with the ultrasonic probe position control unit 36.

The ultrasonic probe 43 includes a transducer transmitting the ultrasonic waves and a transducer receiving the ultrasonic waves. The transducer for transmitting the ultrasonic waves and the transducer for receiving the ultrasonic waves may be integrally formed and may be independently prepared as a separate member. The ultrasonic probe 43 transmits the ultrasonic waves to the measuring target sample 12 through connection with the image control unit 35 according to a command. The ultrasonic probe 43 receives the reflected waves reflected from the measuring target sample 12 and transfers the reflected waves to the body 31. The measuring target sample 12 may be disposed between the ultrasonic transmitting probe and the ultrasonic receiving probe, and the ultrasonic probe 43 may receive the transmitted ultrasonic waves.

The stage 44 includes a surface on which the measuring target sample 12 to be analyzed is mounted in a predetermined region. The analyzing apparatus 41 according to the embodiment includes the water tank 51 such that the measuring target sample 12 and the stage 44 on which the measuring target sample 12 is placed are placed in the water filled in the water tank 51. For example, the stage 44 is disposed in a bottom portion of the water tank 51 and the water tank 51 is fixed by an appropriate fixing stand 52.

The failure position specifying unit 17 includes the image recognition unit 18 and the marking unit driving unit 19. The image recognition unit 18 is connected to the image processing unit 37 and receives the image data that is signal-processed from the image processing unit 37. The image recognition unit 18 according to the embodiment may be the same as the image recognition unit 18 according to the first embodiment by matching a format of the image data received by the image recognition unit 18 with the data format according to the first embodiment. Moreover, if the format of the image data received from the image processing unit 37 is different, the failure position specifying unit 17 may connect a processing block converting to an appropriate format between the image processing unit 37 and the image recognition unit 18. Since the same failure position specifying unit 17 as in the analyzing apparatus 11 according to the first embodiment may be used, detailed description will be omitted. Furthermore, similar to this, it is possible to use the same failure position specifying unit 17 as in the first embodiment in a third and fourth embodiments described below.

The marking unit 50 is moved to an appropriate position by the marking unit driving unit 19. The marking unit 50 acquires a drive signal for attaching a mark indicating the failure position on the measuring target sample 12 through connection with the marking unit driving unit 19 and applies the mark on the measuring target sample 12.

The marking unit 50 may have the same configuration as the marking unit 20 according to the first embodiment, but the marking unit 50 is different from the marking unit 20 of the first embodiment in that the measuring target sample 12 is placed in the water. The marking unit 50 may be operated after removing the water in the water tank 51. In this case, similar to the case of the first embodiment, it is possible to perform the marking on the measuring target sample 12 by emitting the laser beam, pressing the scriber, attaching the seal, or ejecting powder and liquid by the fluid nozzle. If the marking is performed while the water is reserved in the water tank 51, a marking method is limited to the pressing of the scriber or the ejection of the liquid, and the like. Furthermore, a portion of the marking unit 50 submerged in the water requires airtightness. Since the method and configuration of the marking are the same as those of the first embodiment, the detailed description will be omitted.

The analyzing apparatus 41 according to the embodiment operates as described below.

In the analyzing apparatus 41, the ultrasonic transmission unit 33 causes the ultrasonic probe 43 to transmit the ultrasonic waves to the measuring target sample 12, and the ultrasonic receiving unit 34 acquire the reflected waves from the measuring target sample 12, which is received at the ultrasonic probe 43 or the transmitted waves through the measuring target sample 12.

In the analyzing apparatus 41, the image control unit 35 in the body 31 captures the electrical signal of the acquired reflected waves or the transmitted waves, the image processing unit 37 processes the electrical signal and generates image data of the ultrasonic waves.

In the analyzing apparatus 41, the image recognition unit 18 of the failure position specifying unit 17 detects and specifies the failure position from the generated image data and moves the marking unit 50 to the position corresponding to the failure position on surface of the measuring target sample 12.

In the analyzing apparatus 41, the marking unit driving unit 19 causes the marking unit 50 to perform marking on the position corresponding to the failure position on the surface of the measuring target sample 12.

As described above, the analyzing apparatus 41 may specify the failure position by processing the image data acquired through the ultrasonic probe 43, the ultrasonic transmission unit 33, and the ultrasonic receiving unit 34, move the marking unit 50 on the measuring target sample 12, and perform the marking on the position corresponding to the failure position on the surface of the measuring target sample 12 with a predetermined mark. Since it is not necessary for the analyst using the analyzing apparatus 41 to manually compare the image data with the design data of the measuring target sample 12 and the like, it is possible to efficiently perform the failure analysis of the measuring target sample 12.

### Third Embodiment

In the embodiment, a case where the analyzing apparatus is an infrared heat analyzing apparatus will be described. The infrared heat analyzing apparatus applies a voltage to the measuring target sample and captures a radiation image of the infrared light generated by the applied voltage, using an infrared camera. The infrared heat analyzing apparatus repeatedly applies a pulsed voltage to the measuring target sample, acquires an amplitude and a phase of the radiated infrared light, and performs signal processing. Through this process, the infrared heat analyzing apparatus can identify a heat generation position in three dimensions.

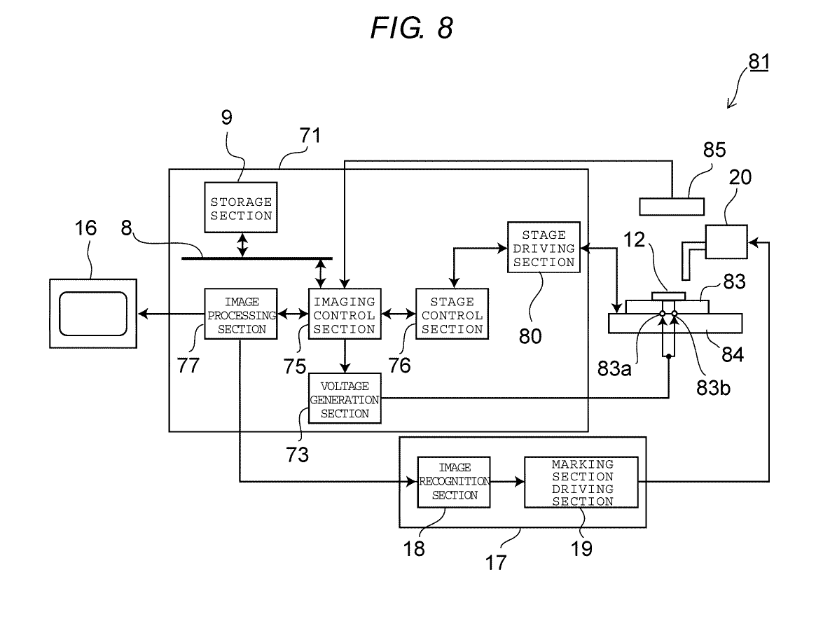

FIG. 8 is a block diagram illustrating an analyzing apparatus 81 according to a third embodiment. The analyzing apparatus 81 according to the embodiment is the infrared heat analyzing apparatus.

The analyzing apparatus 81 according to the embodiment includes a body 71, a stage 84, an infrared camera 85, the failure position specifying unit 17, and the marking unit 20.

The body 71 is connected to the stage 84, the infrared camera 85, and the failure position specifying unit 17. The failure position specifying unit 17 is connected to the infrared camera 85. The body 71 is connected to the infrared camera 85. The body 71 is connected to voltage applying terminals 83a and 83b. The voltage applying terminals 83a and 83b are disposed on a measuring stand 83 provided on the stage 84 and are connected to a power supply terminal of the measuring target sample 12. The body 71 transmits a signal to the stage 84, the infrared camera 85, and the failure position specifying unit 17 and appropriately operates these units. The body 71 applies an appropriate voltage to the power supply terminal of the measuring target sample 12 connected to the measuring stand 83 through connection with the voltage applying terminals 83a and 83b.

The body 71 includes a voltage generation unit 73, an imaging control unit 75, a stage control unit 76, an image processing unit 77, the internal bus 8, and the storage unit 9.

The voltage generation unit 73 is connected to the imaging control unit 75 and applies a voltage to the measuring target sample 12 based on a signal from the imaging control unit 75. The voltage generation unit 73 applies an appropriate voltage to a power supply terminal of the measuring target sample 12 through the voltage applying terminals 83a and 83b provided in the measuring stand 83. For example, the voltage generation unit 73 outputs a repeatedly pulsed voltage of which the amplitude and the phase are controlled. The amplitude and the phase of the pulsed voltage are set based on a signal from the imaging control unit 75.

The imaging control unit 75 is connected to the infrared camera 85 and captures the image signal of the infrared light radiated from the measuring target sample 12 by applying the pulsed voltage. The imaging control unit 75 is connected to the image processing unit 77 and transmits the image signal to the image processing unit 77 to process the image signal captured by the infrared camera 85. The imaging control unit 75 stores the image data processed by the image processing unit 77 in the storage unit 9 through the internal bus 8. The imaging control unit 75 reads the processing data including the image data stored in the storage unit 9 and transfers the processing data to the image processing unit 77.

The image processing unit 77 generates the image data by performing signal processing of the image signal of the infrared light from the imaging control unit 75. Image data includes an amplitude image signal based on the amplitude of the infrared light radiated from the measuring target sample 12 and a phase image signal based on the phase of the radiated infrared light. The image processing unit 77 generates the image data based on the amplitude image signal and the phase image signal according to a command of the imaging control unit 75.

The image processing unit 77 transmits the generated image data to the failure position specifying unit 17 based on the signal of the imaging control unit 75. The image processing unit 77 may transmit the image data to the monitor 16 through connection with the monitor 16.

Since configurations and operations of the imaging control unit 75, the stage control unit 76, the image processing unit 77, the internal bus 8, the storage unit 9, and a stage driving unit 80 are the same as those of the analyzing apparatus 11 according to the first embodiment, the detailed description will be omitted.

The failure position specifying unit 17 includes the image recognition unit 18 and the marking unit driving unit 19. The image recognition unit 18 is connected to the image processing unit 77 and receives from the image processing unit 77 the image data that is signal-processed. It is possible to make the image recognition unit 18 according to the embodiment be the same as the image recognition unit 18 according to the first embodiment by matching the format of the image data received by the image recognition unit 18 with the data format according to the first embodiment. Moreover, if the format of the received image data is different, a processing block converting to an appropriate format may be inserted between the image processing unit 77 and the image recognition unit 18. Thus, since the same failure position specifying unit 17 as in the analyzing apparatus 11 according to the first embodiment may be used, the detailed description will be omitted.

In the present embodiment, since it is not necessary to perform the failure detection in the water and the like the first embodiment, the detailed description will be omitted.

The infrared heat analyzing apparatus may generate the image data based on the amplitude image signal and the phase image signal of the infrared light radiated from the measuring target sample 12. Thus, infrared heat analyzing apparatus may detect, in a nondestructive manner, the failure position of the semiconductor element in three dimensions as a System in Package (SiP).

The analyzing apparatus 81 according to the embodiment is operated as below.

The analyzing apparatus 81 applies an appropriate voltage to the power supply terminal of the measuring target sample 12 by the voltage generation unit 73.

In the analyzing apparatus 81, the infrared camera 85 acquires the radiated infrared image of the measuring target sample 12 generated based on the voltage applied to the power supply terminal of the measuring target sample 12.

In the analyzing apparatus 81, the image processing unit 77 captures the heat image acquired using infrared light through the imaging control unit 75 and generates the image data.

In the analyzing apparatus 81, the image recognition unit 18 of the failure position specifying unit 17 detects and specifies the failure position based on the generated image data and moves the marking unit 20 to the position corresponding to the failure position on the surface of the measuring target sample 12 through the marking unit driving unit 19.

In the analyzing apparatus 81, the marking unit driving unit 19 causes the marking unit 20 to perform the marking on the position corresponding to the failure position on the surface of the measuring target sample 12.

As described above, the analyzing apparatus 81 specifies the failure position by processing the image data acquired by the infrared camera 85 and moves the marking unit 20 to the position corresponding to the failure position on the surface of the measuring target sample 12, and it is possible to perform the marking the measuring target sample 12 with a predetermined mark. Thus, the analyst using the analyzing apparatus 81 may further efficiently perform the failure analysis of the measuring target sample 12 without manually comparing the image data with the design data of the measuring target sample 12.

### Fourth Embodiment

In the embodiment, the analyzing apparatus is an Optical Beam Induced Current (OBIC) and an Optical Beam Induced Resistance Change (OBIRCH) analyzing apparatus. The OBIC/OBIRCH analyzing apparatus applies infrared laser beam to a surface or a rear surface of a measuring target sample, causes the infrared laser beam to excite electrons (OBIC) or causes the infrared laser beam to generate a resistance change by heat generation (OBIRCH). The OBIC/OBIRCH analyzing apparatus measures a current value while performing scan with the infrared laser beam and images and outputs a change in the current value or the resistance value in a two-dimensional plane.

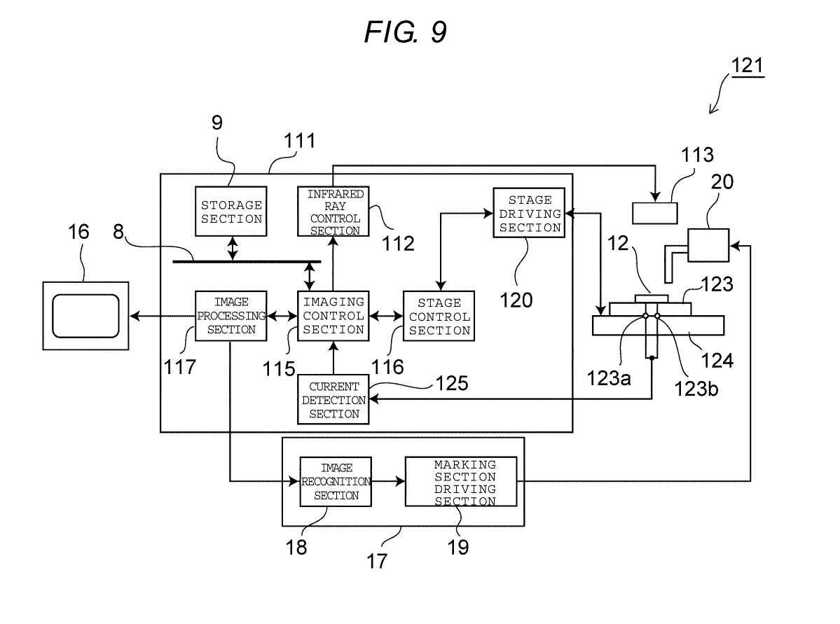

FIG. 9 is a block diaphragm illustrating an example of an analyzing apparatus 121 of a fourth embodiment.

The analyzing apparatus 121 according to the embodiment includes a body 111, an infrared ray irradiation unit 113, a stage 124, a measuring stand 123 having current detection terminals 123a and 123b, the failure position specifying unit 17, and the marking unit 20.

The body 111 is connected to the infrared ray irradiation unit 113, the stage 124, the current detection terminals 123a and 123b, and the failure position specifying unit 17, respectively. The failure position specifying unit 17 is connected to the marking unit 20. The body 111 transmits a signal to the infrared ray irradiation unit 113, the stage 124, and the failure position specifying unit 17, and appropriately controls these units. The body 111 acquires the current value from the current detection terminals 123a and 123b connected to the power supply terminal of the measuring target sample 12.

The body 111 includes an infrared ray control unit 112, an imaging control unit 115, a stage control unit 116, an image processing unit 117, the internal bus 8, the storage unit 9, a stage driving unit 120, and a current detection unit 125.

The infrared ray control unit 112 is connected to the imaging control unit 115, receives a signal from the imaging control unit 115, and controls an infrared laser beam light source of the infrared ray irradiation unit 113. The infrared ray irradiation unit 113 applies the infrared laser beam to the measuring target sample 12 and scans a predetermined region on the measuring target sample 12 under the control of the infrared ray control unit 112.

The current detection unit 125 is connected to the imaging control unit 115, detects the current flowing in the power supply terminal of the measuring target sample 12, and transmits the detected current value to the imaging control unit 115. The stage 124 includes the measuring stand 123 for mounting the measuring target sample 12, and the measuring stand 123 is provided for connection between the power supply terminal of the measuring target sample 12 and the current detection terminals 123a and 123b.

The imaging control unit 115 acquires scanning information used by the infrared ray control unit 112 and the infrared ray irradiation unit 113. The imaging control unit 115 further acquires the current value flowing in the measuring target sample 12. Then, the imaging control unit 115 acquires positional information of the current value based on the scanning information and the current value, and generates two-dimensional image including the current value by cooperating with the image processing unit 117.

The image processing unit 117 generates image data based on the received current value through connection with the imaging control unit 115. The image processing unit 117 outputs the built image data to the monitor 16 according to a command of the imaging control unit 115 and transmits the image data to the failure position specifying unit 17.

Since configuration and operations of the imaging control unit 115, the stage control unit 116, the image processing unit 117, the internal bus 8, the storage unit 9, and the stage driving unit 120 of the body 111 are the same as those of the analyzing apparatus 11 according to the first embodiment, the detailed description will be omitted. Further, since the configurations and the operations of the failure position specifying unit 17 and the marking unit 20 are also the same as those of the analyzing apparatus 11 according to the first embodiment, the description will be omitted.

In the OBIC analyzing apparatus, the current due to photoelectrons excited by irradiation with the infrared ray is detected by the current detection unit 125. In a case of the OBIRCH analyzing apparatus, the change in the resistance value of the semiconductor layer that is changed by the irradiation with the infrared ray is detected by the current detection unit 125 as a current flowing in the semiconductor layer.

The analyzing apparatus 121 according to the embodiment operates as described below.

In the analyzing apparatus 121, the infrared ray irradiation unit 113 scans a predetermined region of the measuring target sample 12. In the analyzing apparatus 121, the current detection unit 125 detects the current value of the region scanned with the infrared ray.

In the analyzing apparatus 121, the imaging control unit 115 and the image processing unit 117 build the image data of the current value of the measuring target sample 12 by mapping a position scanned with the infrared ray and the current value of the position.

In the analyzing apparatus 121, the image recognition unit 18 of the failure position specifying unit 17 detects and specifies the failure position based on the generated image data, and moves the marking unit 20 to the position corresponding to the failure position on the surface of the measuring target sample 12.

In the analyzing apparatus 121, the marking unit 20 performs the marking on the position corresponding to the failure position on the surface of the measuring target sample 12 through the marking unit driving unit 19.

As described above, the analyzing apparatus 121 may specify the failure position by processing the two-dimensional image data based on infrared scanning information of the infrared ray control unit 112. Then, the analyzing apparatus 121 may mark the measuring target sample 12 with a predetermined mark by moving the marking unit 20 to the position corresponding to the failure position on the measuring target sample 12.

According to the embodiments described above, it is possible to specify the failure position by processing the acquired image data and it is possible to apply the mark (laser irradiation mark, scriber mark, seal, ink, powder, light and heat curable epoxy resin, and the like) to the position corresponding to the failure position on the surface of the measuring target sample. Since it is not necessary for the analyst to manually apply the mark to the measuring target sample by referring the CAD data and the like, it is possible to efficiently perform the analysis work. Furthermore, since the analyst may perform the next failure analysis work by using the mark applied to the position corresponding to the failure position on the surface of the measuring target sample, it is possible to efficiently perform the failure analysis. Since the marking unit applying the mark to the position corresponding to the failure position on the surface of the measuring target sample may be selected from a plurality of configurations, a material of the mark applied to the measuring target sample may be appropriately selected depending on an analyzing object, analysis contents, or specification procedures of the analyzing apparatus and the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An analyzing apparatus for a semiconductor device comprising:
an image acquiring unit configured to acquire an image of a sample and generate image data of the acquired image;
a specifying unit configured to specify a failure position of the sample based on the image data; and
a marking unit configured to make a mark on a surface position of the sample that corresponds to the failure position as specified by the specifying unit.

2. The analyzing apparatus according to claim 1, wherein
the marking unit includes a laser processing unit configured to perform laser processing on the surface position of the sample.

3. The analyzing apparatus according to claim 1, wherein
the marking unit includes a holding unit configured to hold an adhesive member on an end thereof and a driving unit configured to move the holding unit such that the adhesive member sticks on the surface position of the sample and remains on the surface position as the mark.

4. The analyzing apparatus according to claim 3, wherein
the adhesive member includes metal.

5. The analyzing apparatus according to claim 1, wherein
the marking unit includes a needle and a driving unit configured to move the needle such that needle scratches the surface position of the sample to form the mark.

6. The analyzing apparatus according to claim 1, wherein
the marking unit includes a discharging unit configured to discharge a powder or a liquid on the surface position of the sample, such that the powder or the liquid remains on the surface position as the mark.

7. The analyzing apparatus according to claim 6, wherein
the powder or the liquid includes metal.

8. The analyzing apparatus according to claim 1, wherein
a specifying unit specifies the failure position based on a comparison of the image data with a design data of the sample.

9. The analyzing apparatus according to claim 1, wherein
the image acquiring unit acquires the image of the sample using at least one of X-ray and infrared ray.

10. The analyzing apparatus according to claim 1, wherein
the image acquiring unit acquires the image of the sample using ultrasonic waves while the sample is submerged in water, and
the marking unit makes the mark while the sample is submerged in the water.

11. A method for making a mark on a semiconductor device sample that is subject to a failure analysis, the method comprising:
acquiring an image of the semiconductor device sample;
generating image data of the acquired image;
specifying a failure position of the semiconductor device sample based on the image data; and
applying a mark on a surface position of the semiconductor device sample that corresponds to the failure position as specified.

12. The method according to claim 11, wherein
applying the mark includes performing laser processing on the surface position of the semiconductor device sample.

13. The method according to claim 11, wherein
applying the mark includes attaching an adhesive member on the surface position of the semiconductor device sample.

14. The method according to claim 13, wherein
the adhesive member includes metal.

15. The method according to claim 11, wherein
applying the mark includes scratching the surface position of the semiconductor device sample.

16. The method according to claim 11, wherein
applying the mark includes discharging a powder or a liquid on the surface position of the semiconductor device sample.

17. The method according to claim 16, wherein
the powder or the liquid includes metal.

18. The method according to claim 11, wherein
specifying the failure position includes comparing the image data with a design data of the semiconductor device sample, and locating the failure position based on the comparison.

19. The method according to claim 11, wherein
the image of the semiconductor device sample is acquired using at least one of X-ray and infrared ray.

20. The method according to claim 11, wherein
the image of the semiconductor device sample is acquired using ultrasonic waves while the semiconductor device sample is submerged in water; and
applying the mark is carried out while the semiconductor device sample is submerged in the water.
